(19) United States
(12) Patent Application Publication
(10) Pub. No.: US 2008/0067625 A1
(43) Pub. Date: Mar. 20, 2008

(54) Semiconductor device

(75) Inventors: Hideo Yamamoto, Kanagawa (JP); Kenya Kobayashi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/898,583

(22) Filed: Sep. 13, 2007

(30) Foreign Application Priority Data
Sep. 14, 2006 (JP) 2006-249813

(51) Int. Cl. H01L 29/78

(52) U.S. Cl. 257/492; 257/E29.262

(57) ABSTRACT

An improved semiconductor device having a gate electrode buried in a trench that a short circuit is hardly generated between a gate electrode and a source electrode at a termination of the gate electrode. A trench is formed in a semiconductor substrate. A gate electrode and a buried insulating film are buried in the trench. A source electrode is provided above the gate electrode via the buried insulating film. At the termination of the gate electrode, an interlayer insulating film is provided between the buried insulating film and the source electrode in such a way that the interlayer insulating film strides over the termination of the trench. Both of the buried insulating film and the interlayer insulating film function as an insulating film and prevent a short circuit at the termination of the gate electrode.

This application is based on Japanese patent application NO. 2006-249813, the content of which is incorporated hereinto by reference.

### BACKGROUND

1. Technical Field

The present invention relates to a semiconductor device.

2. Related Art

For example, Japanese Laid-Open Patent Application Publication No. 2000-252468 and Japanese Laid-Open Patent Application Publication No. 2006-60184 have disclosed a conventional semiconductor device with a trench gate structure. In the above semiconductor devices, a gate electrode and an insulating film covering the gate electrode are buried in a trench.

FIG. 9 is a cross sectional view showing the semiconductor device described in Japanese Laid-Open Patent Application Publication No. 2000-252468. In a semiconductor device 100, an N-type drain region 102, and a P-type well region 103 are sequentially laminated on an N+ type semiconductor body 101. Both of the silicon body 101 and the drain region 102 operate as a drain of a MOSFET. A part of the surface layer of the well region 103 is a P+ type heavily doped body region 104. The semiconductor body 101, the drain region 102, the well region 103, and a heavily doped body region 104 form a semiconductor substrate 110.

A trench 111 is formed in the semiconductor substrate 110. A gate electrode 112 and an insulating film 113 provided thereon are buried in the trench 111. An insulating film 114 and an insulting film 115 are provided under and on the side of the gate electrode 112 respectively. An N+ type source-region 116 is formed between the trench 111 and the above heavily doped body region 104. A source region 116 forms the MOSFET together with the semiconductor body 101, the drain region 102, well region 103, insulating film 115 and the gate electrode 112. The source region 116 is connected to a metal layer 117 provided on the semiconductor substrate 110.

FIG. 10 is a cross sectional view showing a semiconductor device disclosed in Japanese Laid-Open Patent Application Publication. No. 2006-60184. FIG. 9 shows a cross section perpendicular to the longitudinal direction of the trench. On the other hand, FIG. 10 shows a cross section parallel thereto. In a semiconductor device 200, an N-type epitaxial-layer 202 is formed on an N-type silicon body 201. A P-type well region 203 is formed in a part of the surface of the epitaxial layer 202. The silicon body 201, the epitaxial layer 202 and the well region 203 form a semiconductor substrate 210.

A trench 211 is also formed in the above semiconductor substrate 210. A gate electrode 212 is buried in the trench 211. As the gate electrode 212 is housed in the trench 211, the termination of the gate electrode 212 is substantially at the termination 211a of the trench 211. Insulating films 213, 214, and 215 provided on the gate electrode 212 are also buried in the trench 211. Also under the gate electrode 212, an insulating film 216 is provided.

Note that the structure of the gate electrode in the vicinity of the termination of the trench may be roughly classified into the following two types of structures in the semiconductor device with a trench gate structure. One of them is a structure where a portion of a gate electrode 312 is drawn out at a termination 311a of a trench 311 as shown in FIG. 11A. In FIG. 11A, the portion of the gate electrode 312 is extended over an element isolation region 309 formed in a semiconductor substrate 310, and is connected to a gate pad 318. Moreover, an insulating film 313 is buried in the trench 311. The gate electrode 312 and a source electrode 317 are electrically isolated by the insulating film 313 and an interlayer insulating film 321. Here, the element isolation region 309 may be eliminated in FIG. 11A.

The other is a structure where another portion of the gate electrode 312 is not drawn out at the termination 311a of the trench 311 as shown in FIG. 11B. However, it has been found that the above structures have the following problems. That is, the above structures are obtained by etching to remove a gate material 312a at the outside of the trench 311, provided across the inside and the outside of the trench 311 as shown in FIG. 12A.

However, in the vicinity of the termination 311a of the trench 311, the gate material 312a is thicker for a difference in level in comparison with other part of the trench 311. Accordingly, in the vicinity of the termination 311a of the trench 311, the gate electrode 312 obtained by etching the gate material 312a also remains thicker in comparison with other part of the trench 311. That is, in the vicinity of the termination 311a of the trench 311, the insulating film 313 on the gate electrode 312 becomes thinner in comparison with other part. Thereby, a short circuit is easily generated between the gate electrode 312 and the source electrode 317.

### SUMMARY

According to the present invention, a semiconductor device including: a trench formed in a semiconductor substrate; a gate electrode buried in the trench; a source electrode provided above the gate electrode; and an insulating film, which is provided between the gate electrode and the source electrode in such a way that the insulating film strides over the termination of the trench, and a part of the insulating film is buried in the trench.

In the above semiconductor device, insulating film is provided between the gate electrode and the source electrode in such a way that the insulating film strides over the termination of the trench. Accordingly, even when the thickness of a part of the insulating film, buried in the trench, is thin in the vicinity of the termination of the trench, the thickness of the related insulating film between the gate electrode and the source electrode may be secured enough. Accordingly, a short circuit may be prevented from being generated between the gate electrode and the source electrode.

According to the present invention, a semiconductor device with a structure in which a short circuit is hardly generated between a gate electrode and a source electrode may be realized.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view showing one embodiment of a semiconductor device according to the present invention;

FIG. 2A is a plan view showing a portion enclosed with a dotted line L1 in FIG. 1;

FIG. 2B is an enlarged plan view showing a portion enclosed with a dotted line L3 in FIG. 2A;

FIG. 3 is a sectional view taken along a line III-III in FIG. 2A and FIG. 2B;

FIG. 4 is an enlarged cross sectional view showing a part of FIG. 3;

FIG. 5 is a plan view showing a portion enclosed with a dotted line L2 in FIG. 1;

FIG. 6 is a cross sectional view taken along a line VI-VI in FIG. 5;

FIG. 7 is a plan view for explaining a modification of the embodiments;

FIG. 8A and FIG. 8B are a plan view for explaining a modification of the embodiments;

FIG. 9 is a cross sectional view showing a conventional semiconductor device;

FIG. 10 is a cross sectional view showing another conventional semiconductor device;

FIG. 11A and FIG. 11B are a cross sectional view for explaining problems to be solved by the present invention; and

FIG. 12A and FIG. 12B are a cross sectional view for explaining problems to be solved by the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Hereinafter, preferable embodiments of a semiconductor device according to the present invention will be explained in detail, referring to drawings. Here, when the drawings are explained, similar components will be denoted by same reference numerals in all drawings, and same description will not be repeated.

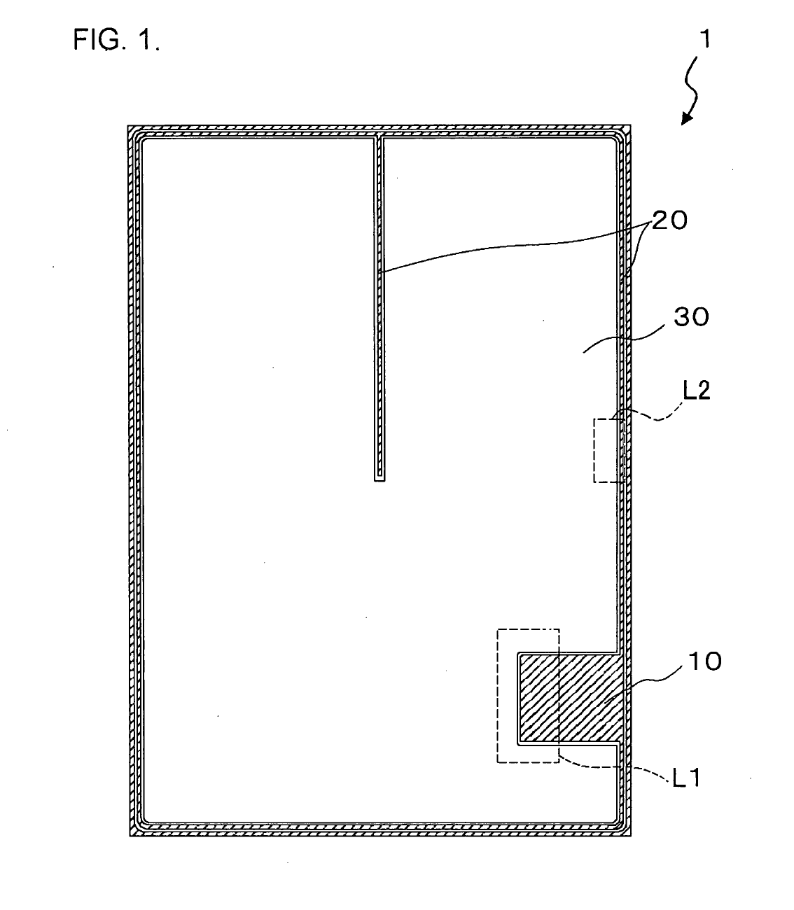

FIG. 1 is a plan view showing one embodiment of the semiconductor device according to the present invention. A semiconductor device 1 includes: a gate pad 10; a gate finger 20; and a source electrode 30. A material for the gate pad 10 and the source electrode 30 may include, for example, aluminum. A material for the gate finger 20 may include, for example, poly-silicon. And, the gate finger 20 may be laminated with aluminum thereon, for example.

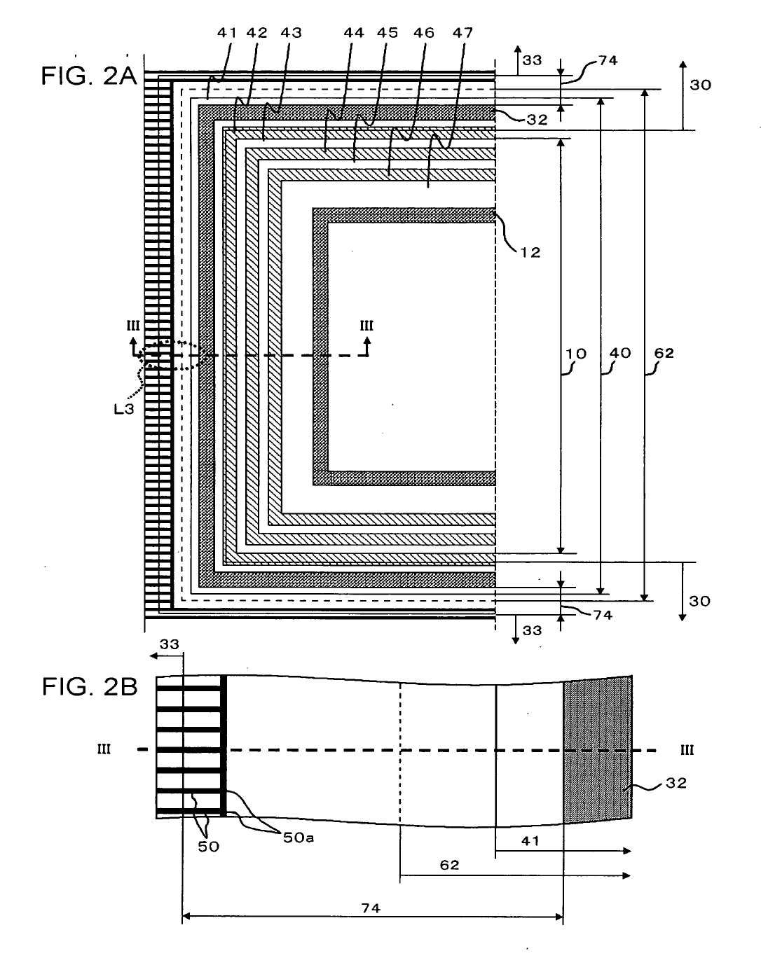

FIG. 2A is a plan view showing the vicinity (a portion enclosed with a dotted line L1 in FIG. 1) of the gate pad 10 in the semiconductor device 1. As shown in FIG. 2A, the semiconductor device 1 includes a Zener diode 40. The Zener diode 40 is connected between the source electrode 30 and the gate pad 10 to be described later. The Zener diode 40 is formed with N+ type regions 41, 43, 45, and 47, and P type regions 42, 44, and 46. A material for the regions 41 through 47 may include, for example, poly-silicon. A part of the region 41 serves as a source contact 32 and a part of the region 47 serves as a gate contact 12.

FIG. 2B is an enlarged plan view showing a portion enclosed with a dotted line L3 in FIG. 2A. As shown in FIG. 2B, a plurality of trenches 50 arranged like a stripe are formed. In the present embodiment, terminations 50a of the trenches 50 are connected to one another. Thus, the plurality of trenches 50 and the terminations 50a are combined and formed a single trench. Here, the termination 50a of each trench 50 is defined as a termination of the related trench 50 in longitudinal direction.

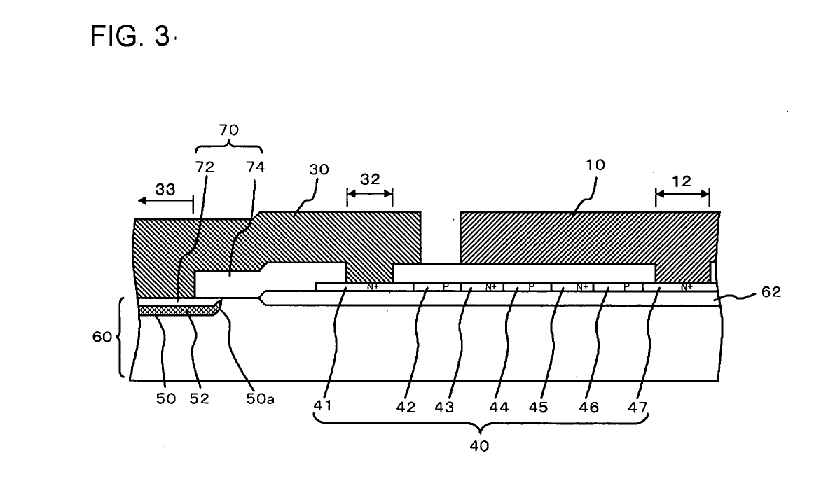

FIG. 3 is a sectional view taken along a line III-III in FIG. 2A and FIG. 2B. As seen from FIG. 3, the trench 50 is formed in a semiconductor substrate 60. The semiconductor substrate 60 is a silicon substrate in the present embodiment. A gate electrode 52 is buried in the trench 50. In FIG. 3, the gate electrode 52 is not drawn out at the termination 50a of the trench 50. The reason is that the gate electrode 52 should not be connected directly to the region 41 serving as a source contact. Accordingly, the gate electrode 52 is housed in the trench 50 via gate insulating film (not shown), and the termination of the gate electrode 52 is substantially at the termination 50a of the trench 50. Here a material for the gate electrode 52 may include poly-silicon, or a metal material, such as tungsten.

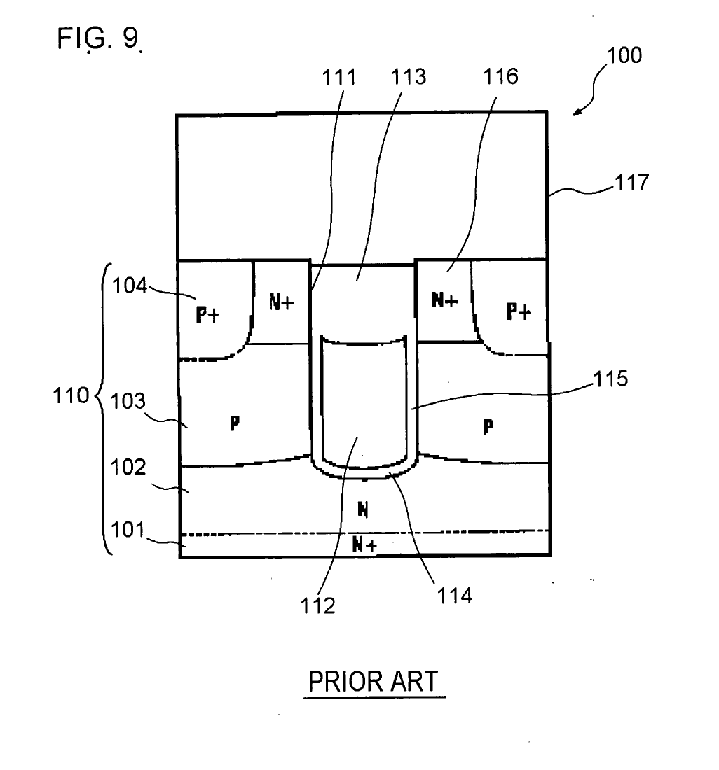

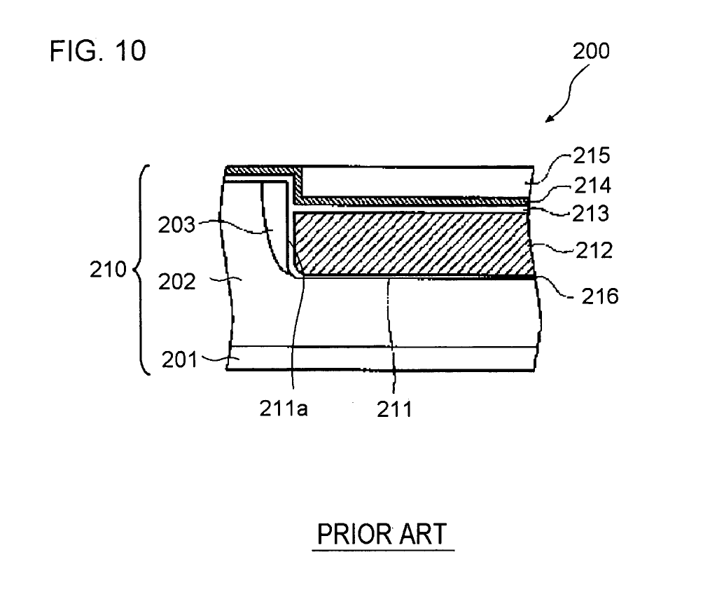

The source electrode 30 is provided above the gate electrode 52 and contacts to a source region (not shown) and a heavily doped body region (not shown) at a source contact 33 similarly shown in FIG. 9. The source electrode 30 strides over the termination 50a of the trench 50.

An insulating film 70 is provided between the gate electrode 52 and the source electrode 30, striding over the termination 50a of the trench 50. As the termination 50a of the trench 50 is substantially at the termination of the gate electrode 52 as described above, the insulating film 70 strides over not only the termination 50a of the trench 50, but also the termination of the gate electrode 52.

A part of the above insulating film 70 is buried in the trench 50. Specifically, the insulating film 70 includes: a buried insulating film 72 (first insulating film) located in the trench 50; and an interlayer insulating film 74 (second insulating film) located outside of the trench. The buried insulating film 72 is corresponding to a part of the insulating film 70, buried in the trench 50. And, the interlayer insulating film 74 is corresponding to a part striding over the termination 50a of the trench 50. A material for the buried insulating film 72, and the interlayer insulating film 74 may include, for example, Non-doped Silicate Glass (NSG), or Boron-Phosphorus Silicate Glass (BPSG). The material of the buried insulating film 72, and that of the interlayer insulating film 74 may be either the same or different.

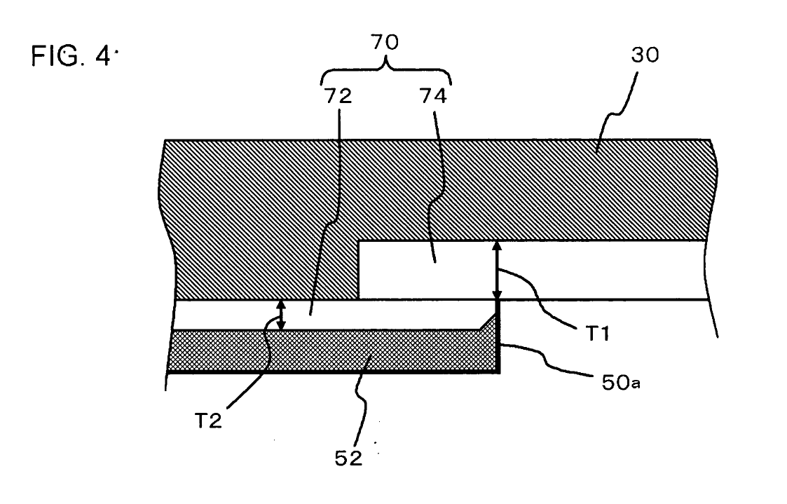

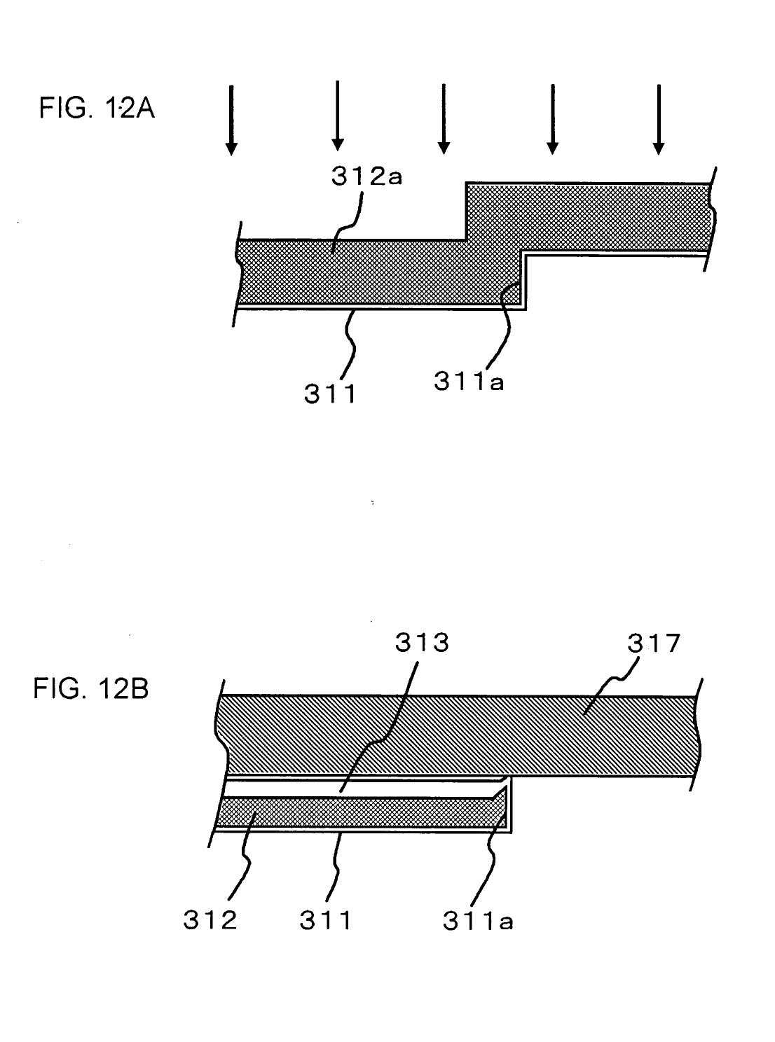

FIG. 4 is an enlarged cross sectional view showing a part of FIG. 3. The thickness T1 of the interlayer insulating film 74 at the termination 50a of the trench 50 is preferably equal to or more than the maximum value T2 of the thickness of the buried insulating film 72. As explained by use of FIG. 12B, the thickness of the buried insulating film 72 in the vicinity of the termination 50a of the trench 50 is thinner than that of other part of the buried insulating film 72. Accordingly, the thickness of other part of the buried insulating film 72 is corresponding to the above-described maximum value T2. The above maximum value T2 is, for example, about 0.1 to 0.5 micrometers.

Returning to FIG. 3 the N+ type regions 41, 43, 45, and 47, and the P type regions 42, 44, and 46, all of which forming the Zener diode 40, are formed on an element isolation region 62 formed in the semiconductor substrate 60. The source electrode 30 is connected to the region 41, and the gate pad 10 is connected to the region 47. Here, the element isolation region 62 is of a Local Oxidation of Silicon (LOCOS), or Shallow Trench Isolation (STI), for example.

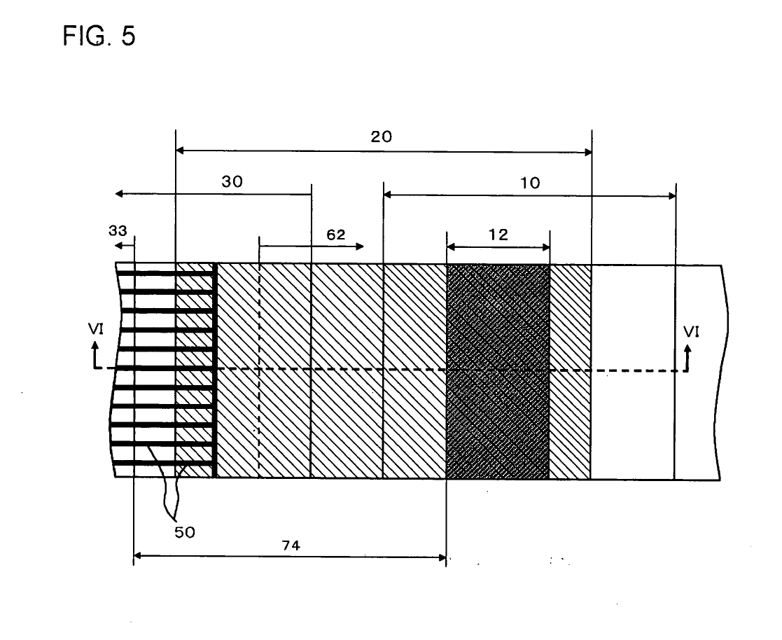

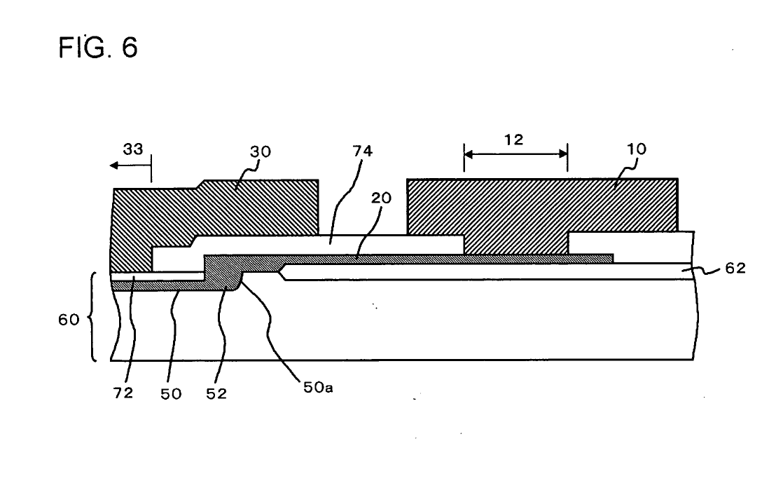

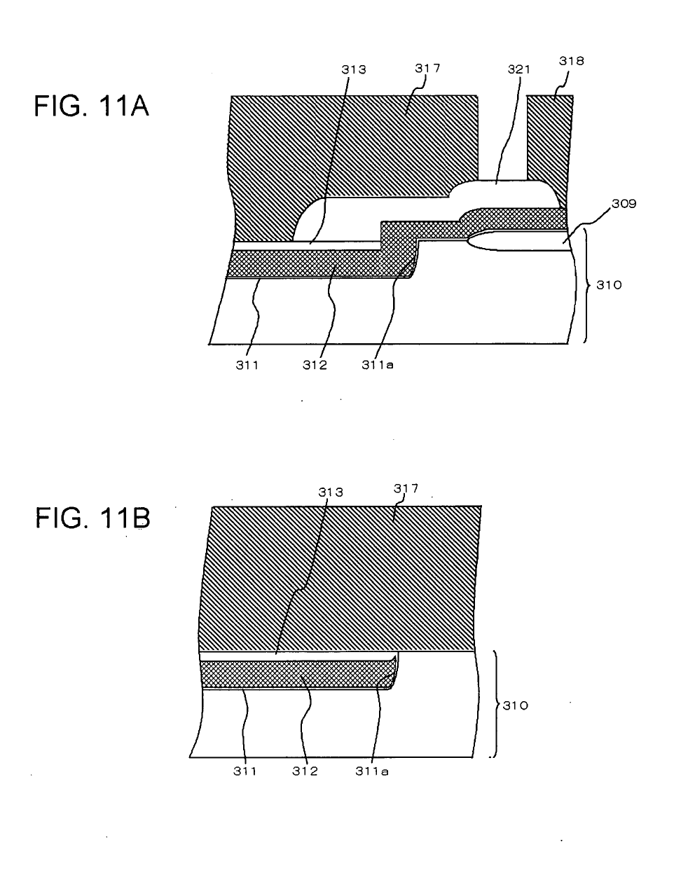

FIG. 5 is a plan view showing a portion (portion enclosed with a dotted line L2 in FIG. 1) of the semiconductor device 1. FIG. 6 is a cross sectional view taken along a VI-VI line in FIG. 5. In FIG. 6, the gate electrode 52 is drawn out at the termination 50a of the trench 50. The gate electrode 52 is extended onto the element isolation region 62, and is connected to the gate pad 10 via the gate finger 20. Accordingly, the gate electrode 52 is not housed in the trench 50. A portion of the gate electrode 52 located outside of the trench 50 is corresponding to the gate finger 20 in FIG. 5. And, a buried insulating film 72 is also buried in the trench 50. However, unlike the buried insulating film 72 formed in the vicinity of the Zener diode 40 shown in FIG. 3, the buried insulating film 72 does not reach the termination 50a of the trench 50 because the gate electrode 50 is extended over the semiconductor substrate 60 as shown in FIG. 11A. The gate electrode 52 and the source electrode 30 are electrically isolated by the buried insulating film 72 and an interlayer insulating film 74.

Advantages according to the present embodiment will be explained. In the semiconductor device 1, the insulating film 70 is provided between the gate electrode 52 and the source electrode 30 in such a way that the interlayer insulating film 74 strides over the termination 50a of the trench 50 (refer to FIG. 3). Accordingly, even when the thickness of a part of the insulating film 70, buried in the trench 50 that is a buried insulating film 72, is thin in the vicinity of the termination 50a of the trench 50, the thickness of the insulating film 70 of a combination of both of the buried insulating film 72 and the interlayer insulating film 74 may be secured enough. Accordingly, a short circuit may be prevented from being generated between the gate electrode 52 and the source electrode 30. The above structure may be obtained by simply changing a mask pattern for forming a contact.

When the thickness T1 of the interlayer insulating film 74 at the termination 50a of the trench 50 (refer to FIG. 4) is equal to or more than the maximum value T2 of the thickness of the buried insulating film 72, the above generation of a short circuit may be more effectively prevented. The reason is that, when T1≧T2, a thickness equal to or more than the maximum value T2 may be surely secured for the thickness of the insulating film 70 as a whole at the termination 50a of the trench 50.

When the buried insulating film 72 is formed with NSG, a dopant may be prevented from flowing out from the buried insulating film 72 at heat treatment. The same holds true for a case in which the interlayer insulating film 74 is formed with NSG.

The Zener diode 40 is connected between the gate electrode 52 and the source electrode 30. Thereby, MOSFET may be protected from a surge voltage.

The gate electrode 52 and the insulating film (the buried insulating film 72) covering the gate electrode 52 are buried in the trench 50. Thereby, as with the above-mentioned semiconductor device shown in FIG. 9, a lateral distance between a contact edge formed between the source electrode 30 and the source region and an edge of the gate electrode 52 can be made smaller in comparison with that of a case in which the insulating film is formed above the trench 50 and stride over a part of the source region.

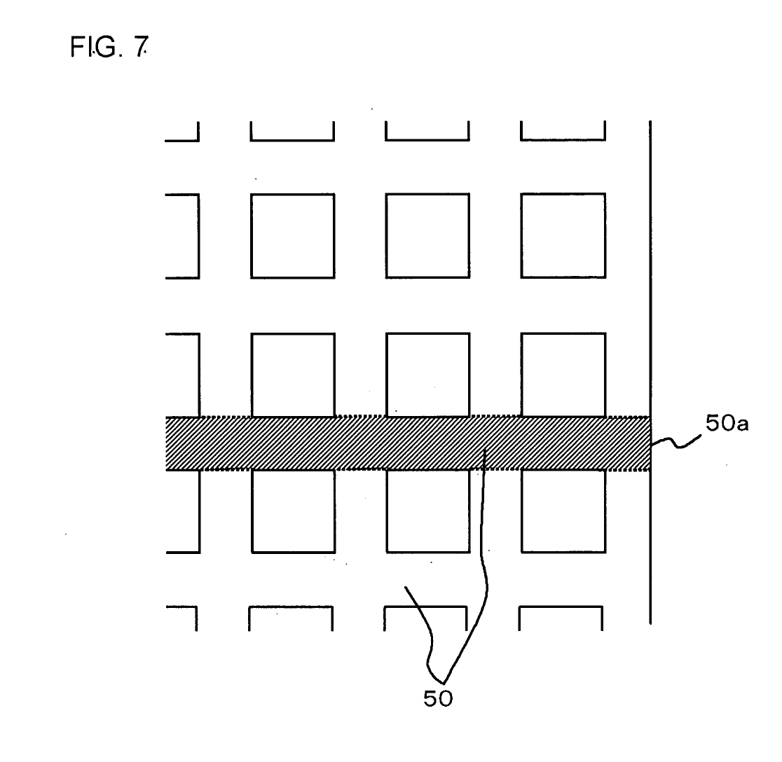

The semiconductor device according to the present invention is not limited to the above-described embodiments, but various modifications are possible. Though the above-described embodiments have illustrated the trench 50 arranged like a stripe, trench 50 may be arranged like a mesh as shown in FIG. 7. Also in the above configuration, the termination of a certain portion of the trench 50 (for example, the hatched portion of the trench 50) in longitudinal direction is corresponding to the termination 50a of the related portion of the trench 50.

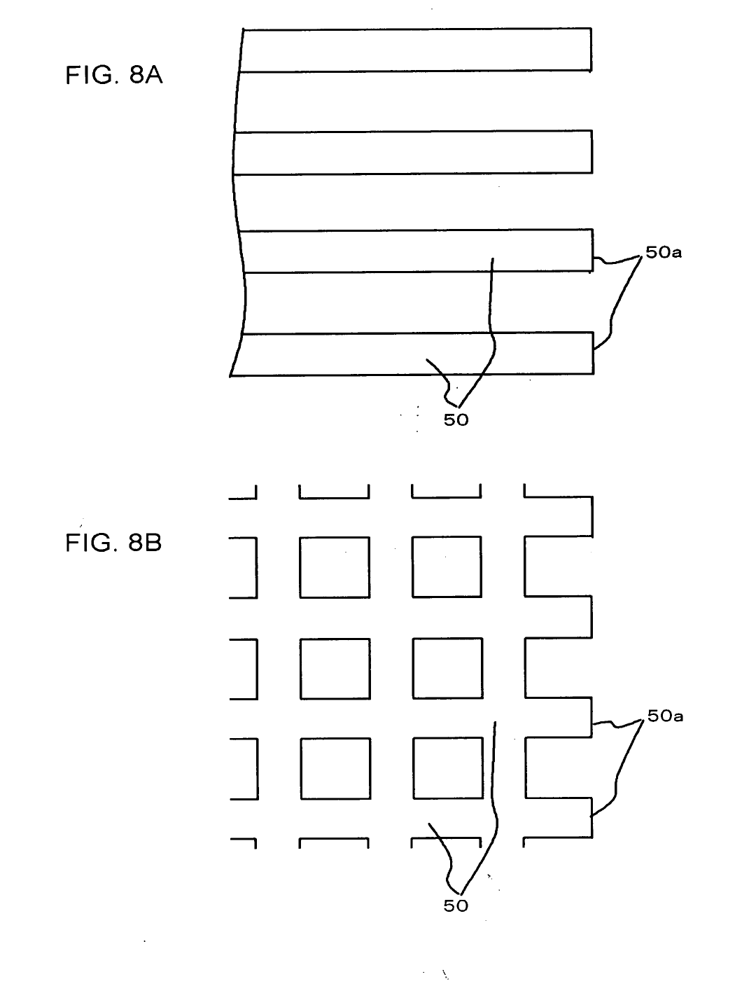

Moreover, the above-described embodiments have shown one example in which the terminations 50a of a plurality of the trenches 50 are connected to one another. Thus, the plurality of trenches 50 and the terminations 50a are combined and formed a single trench. Though, the terminations 50a of the trenches 50 may not be connected to one another. FIGS. 8A and 8B show an example in which the terminations 50a of the trenches 50 are not connected to one another, for cases where the trenches 50 are arranged like a plurality of stripe-shaped trenches and like a single mesh-shaped trench respectively.

Moreover, the above-described embodiments have explained that a structure, in which the gate electrode 52 is not drawn out, is made at the termination 50a of the trench 50 in an area in which the Zener diode 40 is provided. However, the above-described structure may be made in rest area. Even in the above case, it is obvious that a short circuit may be prevented from being generated between the gate and the source by providing the insulating film 70 striding over the termination 50a.

Moreover, though the above-described embodiments have shown one example in which the gate finger 20 is provided in the semiconductor device 1, the gate finger 20 may be eliminated.

It is apparent that the present invention is not limited to the above embodiment, and may be modified and changed without departing from the scope and spirit of the invention.

What is claimed is:

1. A semiconductor device, comprising:
a trench formed in a semiconductor substrate;
a gate electrode buried in said trench;
a source electrode provided above said gate electrode; and
an insulating film, which is provided between said gate electrode and said source electrode in such a way that said insulating film strides over the termination of said trench, and a part of said insulating film is buried in said trench.

2. The semiconductor device as claimed in claim 1,
wherein said gate electrode is housed in said trench.

3. The semiconductor device as claimed in claim 1,
wherein said source electrode strides over said termination of said trench.

4. The semiconductor device as claimed in claim 1,
wherein said insulating film includes: a first insulating film located inside of said trench; and a second insulating film located outside of said trench, and
said second insulating film strides over said termination of said trench.

5. The semiconductor device as claimed in claim 4,
wherein the thickness of said second insulating film at said termination of said trench is equal to or more than the maximum value of the thickness of said first insulating film.

6. The semiconductor device as claimed in claim 4,
wherein at least one of said first and second insulating film comprises at least one of NSG and BPSG.

7. The semiconductor device as claimed in claim 1,
comprising a Zener diode connected between said gate electrode and said source electrode.

8. The semiconductor device as claimed in claim 6,
wherein said first and second insulating films comprise NSG.
